(19) United States
(12) Patent Application Publication
(10) Pub. No.: US 2026/0089857 A1
(43) Pub. Date: Mar. 26, 2026

(54) FLIP APPARATUS AND ELECTRONIC DEVICE

(71) Applicant: Lenovo (Beijing) Limited, Beijing (CN)

(72) Inventor: Lei WANG, Beijing (CN)

(21) Appl. No.: 19/222,689

(22) Filed: May 29, 2025

(30) Foreign Application Priority Data
May 31, 2024 (CN) 202410705700.4

(51) Int. Cl. H05K 5/02

(52) U.S. Cl. CPC H05K 5/0226

(57) ABSTRACT

A flip apparatus includes a first friction component and a second friction component. The first friction component is arranged between a first moving component and a second moving component that move relative to each other. The second friction component is arranged between the second moving component and a third moving component that move relative to each other. The first friction component is different from the second friction component. When the flip apparatus moves from a first status to a second status, and the first friction component and the second friction component jointly provide a damping force.

### CROSS-REFERENCE TO RELATED APPLICATION

The present disclosure claims priority to Chinese Patent Application No. 202410705700.4, filed on May 31, 2024, the entire content of which is incorporated herein by reference.

### TECHNICAL FIELD

The present disclosure relates to the encoding and decoding technology field and, more particularly, to an image encoding method and an image decoding method.

### BACKGROUND

A flip mechanism is widely used in a mechanical device, an electronic device, etc. The required function of the device can be realized through the flipping action of the flip mechanism.

Electronic devices that are configured to open and close not only need to be light and thin, but also require a rotation shaft to provide sufficient damping force to support the devices during the opening and closing process and opening and closing to a specific posture, such as a notebook or a folding cell phone being unfolded from 90° to 127°. A single damping component is usually configured to provide the damping force. For example, the rotation shaft needs to be thickened, or a plurality of rotation shafts are provided, which does not conform to the trend of pursuing lightness and thinness for opening and closing electronic devices.

### SUMMARY

An aspect of the present disclosure provides a flip apparatus, including a first friction component and a second friction component. The first friction component is arranged between a first moving component and a second moving component that move relative to each other. The second friction component is arranged between the second moving component and a third moving component that move relative to each other. The first friction component is different from the second friction component. When the flip apparatus moves from a first status to a second status, and the first friction component and the second friction component jointly provide a damping force.

An aspect of the present disclosure provides an electronic device, including a first body, a second body, and a flip apparatus. The first body and the second body are switched from a first relative position to a second relative position through the flip apparatus. When the first body and the second body are switched from the first relative position to the second relative position, a first friction component and a second friction component of the flip apparatus jointly provide a damping force. The first friction component is different from the second friction component.

### BRIEF DESCRIPTION OF THE DRAWINGS

FIG. 1 illustrates a schematic local exploded diagram of a flip apparatus according to some embodiments of the present disclosure.

FIG. 2 illustrates a schematic local structural diagram of a flip apparatus in a first status according to some embodiments of the present disclosure.

FIG. 3 illustrates a schematic local structural diagram of a flip apparatus in a second status according to some embodiments of the present disclosure.

FIG. 4 illustrates a schematic exploded diagram of a flip apparatus according to some embodiments of the present disclosure.

FIG. 5 illustrates a schematic assembly diagram of a first moving component, a second moving component, and a first trajectory group according to some embodiments of the present disclosure.

FIG. 6 illustrates a schematic exploded diagram of a first moving component, a second moving component, and a first trajectory group according to some embodiments of the present disclosure.

FIG. 7 illustrates a schematic structural diagram of a second friction component according to some embodiments of the present disclosure.

FIG. 8 illustrates a schematic structural diagram of a second friction component according to some embodiments of the present disclosure.

FIG. 9 illustrates a schematic structural diagram of a flip apparatus in a first status according to some embodiments of the present disclosure.

FIG. 10 illustrates a schematic structural diagram of a flip apparatus in a second status according to some embodiments of the present disclosure.

FIG. 11 illustrates a schematic structural diagram of a flip apparatus in a first status according to some embodiments of the present disclosure.

FIG. 12 illustrates a schematic structural diagram of a flip apparatus in a second status according to some embodiments of the present disclosure.

FIG. 13 illustrates a schematic structural diagram of an electronic device in a folded status according to some embodiments of the present disclosure.

FIG. 14 illustrates a schematic structural diagram of an electronic device in an unfolded status according to some embodiments of the present disclosure.

### REFERENCE NUMERALS

| | | | | | |
|---|---|---|---|---|---|
| 10 | First moving component | 101 | Sliding groove | 11 | First fixing block |
| 12 | Second fixing block | 20 | Second moving component | 201 | Sliding rail |
| 21 | First drive arm | 22 | Second drive arm | 30 | Third moving component |
| 31 | First core shaft | 32 | Second core shaft | 40 | First friction component |
| 50 | Second friction component | 51 | First cam | 511 | First protrusion |
| 52 | Second cam | 521 | Second protrusion | 52′ | Second cam |
| 53 | Torsion spring | 60 | Base | 71 | First support plate |
| 72 | Second support plate | 81 | First trajectory group | 82 | Second trajectory group |
| 91 | First drive gear | 92 | Second drive gear | 100 | First body |
| 200 | Second body | | | | |

### DETAILED DESCRIPTION OF THE EMBODIMENTS

Embodiments of the present disclosure are described with reference to the accompanying drawings. However, these descriptions are merely exemplary and are not intended to limit the scope of the present disclosure. Furthermore, descriptions of well-known structures and techniques are omitted below to avoid unnecessarily obscuring the concepts of the present disclosure.

The terms used herein are only for describing specific embodiments and are not intended to limit the present disclosure. The terms “comprising,” “including,” etc., used herein can indicate the presence of the described features, steps, operations, and/or components, but do not preclude the presence or addition of one or more other features, steps, operations, or components.

All terms (including technical and scientific terms) used herein have the meanings commonly understood by those skilled in the art unless otherwise defined. The terms used herein should be interpreted as having meanings consistent with the context of the present disclosure and should not be interpreted in an idealized or overly rigid manner.

In the flip mechanism of the existing technology, a single damping component is usually configured to provide a damping force to perform a retarding and buffering function on the moving mechanism to cause the movement to be smoother and more stable. The damping component usually includes a rotation shaft and a cam arranged at the rotation shaft. To provide a sufficient damping force, the sizes of the rotation shaft and the cam can be relatively large, which is not beneficial for the miniaturization or slim design of the device.

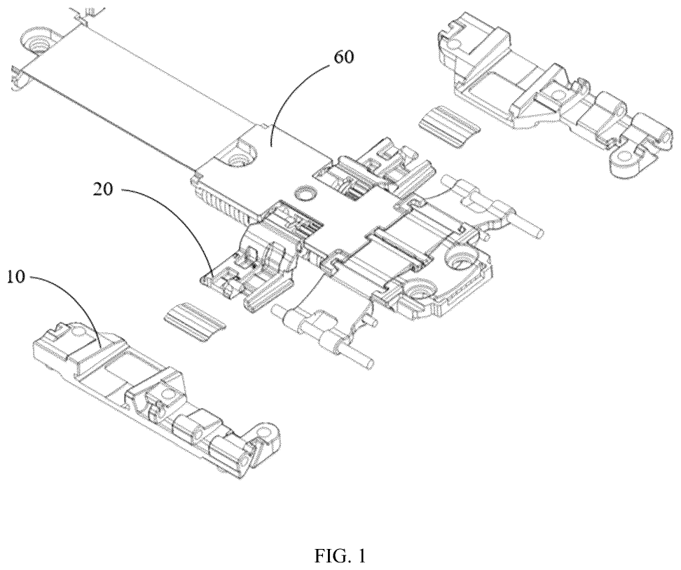

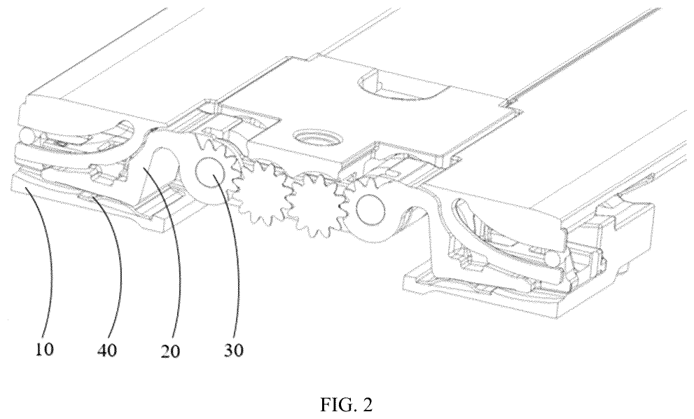

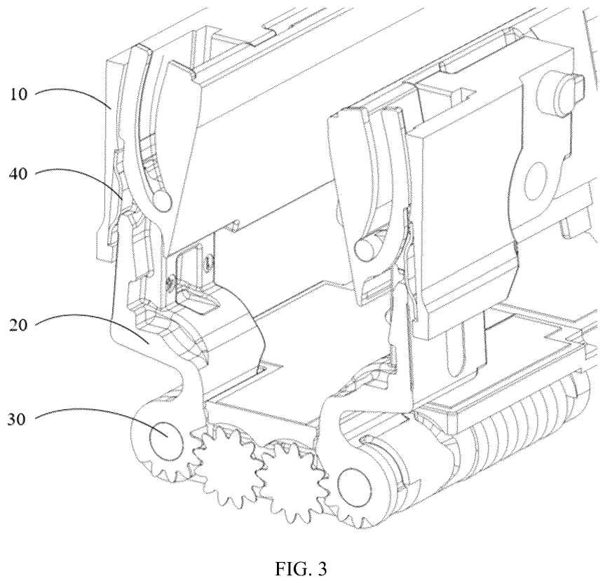

FIG. 1 illustrates a schematic local exploded diagram of a flip apparatus according to some embodiments of the present disclosure. FIG. 2 illustrates a schematic local structural diagram of a flip apparatus in a first status according to some embodiments of the present disclosure. FIG. 3 illustrates a schematic local structural diagram of a flip apparatus in a second status according to some embodiments of the present disclosure.

In embodiments of the present disclosure, as shown in FIG. 1, FIG. 2, and FIG. 3, the flip apparatus includes a first friction component 40, a second friction component 50. The first friction component 40 is arranged between the first moving component 10 and the second moving component 20 that move relatively. The second friction component 50 is arranged between the second moving component 20 and a third moving component 30 that move relatively. The first friction component 40 is different from the second friction component 50. When the flip apparatus moves from a first status to a second status, the first friction component 40 and the second friction component 50 can operate together to provide a damping force.

In some embodiments, the flip apparatus includes the first moving component 10, the second moving component 20, and the third moving component 30. At least one of the first moving component 10, the second moving component 20, and the third moving component 30 can be connected to the flipping component. The corresponding function of the flipping component can be realized when the flip apparatus switches between the first status and the second status.

For example, the flip apparatus can be applied in a device that needs to open and close an opening. The flipping component can be a cover plate configured to open and close the opening. The cover plate can be connected to the flip apparatus. In the first status, the cover plate can close the opening. When the flip apparatus moves from the first status to the second status, the cover plate can flip from a first position to a second position to open the opening.

The flip apparatus can be applied in an electronic device having a form transformation. The flipping component can be a first body and a second body that switch between an unfolded status and a folded status. The first body and the second body can be connected to the flip apparatus. In the first status, the first body and the second body can be in the unfolded status, and the first body and the second body can have an angle of 180 degrees. When the flip apparatus moves to the second status from the first status, the first body and the second body can switch to the folded status from the unfolded status. The first body and the second body can have an angle of 0 degree or close to 0 degree.

The second moving component 20 can be configured to connect the first moving component 10 and the third moving component 30 and transmit motion between the first moving component 10 and the third moving component 30. The flip apparatus further includes a base 60. At least one of the first moving component 10, the second moving component 20, and the third moving component 30 can be mounted at the base 60. The base 60 can provide a mounting basis for the first moving component 10, the second moving component 20, and the third moving component 30.

The first moving component 10 can have a first relative movement relationship with the second moving component 20. For example, one of the first moving component 10 and he second moving component 20 can move linearly, curvilinearly, or rotationally relative to the other.

The second moving component 20 can have a second relative movement relationship with the third moving component 30. For example, one of the second moving component 20 and the third moving component 30 can move linearly, curvilinearly, or rotationally relative to the other one.

The first friction component 40 can be located between the first moving component 10 and the second moving component 20. For example, the first friction component 40 can be clamped between the opposing surfaces of the first moving component 10 and the second moving component 20 and can be fixed to the first moving component 10 or the second moving component 20. During the relative movement of the first moving component 10 and the second moving component 20, the first friction component 40 can provide sliding friction.

The second friction component 50 can be located between the second moving component 20 and the third moving component 30 that move relatively. For example, the second moving component 20 and the third moving component 30 can rotate relative to each other. The second friction component 50 can be arranged at the contact surface where the second moving component 20 and the third moving component 30 rotate relative to each other. During the relative rotation, the second friction component 50 can provide rotational friction or torque.

The flip apparatus can switch between the first status and the second status. To facilitate the description, a flip apparatus with a folding function can be used as an example. The first status can refer to the unfolded status, and the second status can refer to the folded status.

During the relative movement of the first moving component 10 and the second moving component 20, the first friction component 40 can provide a part of the damping force for the whole motion system. During the relative movement of the second moving component 20 and the third moving component 30, the second friction component 50 can provide the other part of the damping force for the whole motion system. The first friction component 40 and the second friction component 50 can be arranged at different positions in the system. The first friction component 40 and the second friction component 50 can jointly provide the damping force required to switch statuses for the system.

The positional relationships of the first moving component 10, the second moving component 20, and the third moving component 30 relative to the base 60 may not be limited. At least one of the first moving component 10, the second moving component 20, or the third moving component 30 can rotate. For example, the second moving component 20 can rotate, and a central axis of the second moving component 20 can be aligned with a rotation axis of the flip apparatus. The second moving component 20 and components having a connection relationship with the second moving component 20 can be designed with small dimensions.

The first friction component 40 and the second friction component 50 can be configured to provide the required damping force for the status switching of the flip apparatus. The first friction component 40 and the second friction component 50 can be arranged at different positions of the flip apparatus to satisfy the required damping force when the flip apparatus switches between the first status and the second status and at least a part of the first moving component 10, the second moving component 20, and the third moving component 30 have a small size.

In some embodiments, the first friction component 40 can be arranged between the first moving component 10 and the second moving component 20 that move relatively. The second friction component 50 can be arranged between the second moving component 20 and the third moving component 30 that move relatively. The first friction component 40 and the second friction component 50 can be arranged at different positions of the flip apparatus. When the flip apparatus switches between the first status and the second status, the first friction component 40 and second friction component 50 can jointly provide the damping force to satisfy the required damping force when the flip apparatus switched statuses and at least a part of the first moving component 10, the second moving component 20, and the third moving component 30 have a small size. Thus, the miniaturization or slim design of the flip apparatus can be facilitated.

In embodiments of the present disclosure, when the flip apparatus moves from the first status to the second status, the first friction component 40 can provide a constant damping force, while the second friction component 50 can provide a changing damping force.

In some embodiments, the first moving component 10 and the second moving component 20 can be connected via a sliding structure. For example, the first moving component 10 can include a slide rail, while the second moving component 20 can include a slide groove. The slide rail can slidably match with the slide groove. In some other embodiments, the first moving component 10 can include the slide groove, and the second moving component 20 can include the slide rail. The slide rail can slidably cooperate with the slide groove.

During the relative sliding between the first moving component 10 and the second moving component 20, the first friction component 40 can remain in s sliding friction status with either the first moving component 10 or the second moving component 20. The first friction component 40 can generate the sliding friction to provide a constant damping force for the system. Thus, the flip apparatus can remain stable in the first status or the second status.

The second moving component 20 and third moving component 30 can rotate relative to each other. The second friction component 50 can include a cam, a concave wheel, and a spring that are coaxially arranged between the second moving component 20 and the third moving component 30. During relative rotation between the second moving component 20 and the third moving component 30, the cam can roll on the curved surface of the concave wheel. The concave wheel can move axially and compress the spring. The damping force can change as the spring compression amount changes.

Alternatively, the second friction component 50 may include a pair of intermeshing gear components and a spring arranged coaxially. The gear components include a first gear and a second gear movable axially. During relative rotation between the first gear and the second gear, the second gear is driven to move axially and compress the spring. As the spring compression amount changes, a changing damping force is generated.

The changing trend of the changing damping force can be from small to large, and then from large to small. According to the application requirement, the changing trend of the changing damping force can fluctuate.

When the flip apparatus switched between the unfolded status and the folded status, the changing damping force can provide a good opening/closing tactile feedback for the flip apparatus.

In some embodiments, when the flip apparatus switches from the first status to the second status, the first friction component 40 can provide a constant damping force acting on the whole system, while the second friction component 50 can provide a changing damping force mainly acting on the rotation component. The stable damping force required for status switching of the system can be provided through the constant damping force and the changing damping force. Thus, the stability of the flip apparatus can be ensured in the first status and the second status. Meanwhile, the stability of the movement when the flip apparatus switches between the statuses can be ensured to provide good opening and closing tactile feedback.

In embodiments of the present disclosure, as shown in FIGS. 2 and 3, the first friction component 40 provides a damping force along a first moving path between the first moving component 10 and second moving component 20. The first moving path is linear. The second friction component 50 provides a damping force along a second moving path between the second moving component 20 and the third moving component 30. The second moving path is an arc.

In some embodiments, the first moving component 10 and the second moving component 20 can have a first moving path that is linear. For example, the first moving component 10 can include an accommodation groove accommodating the second moving component 20. Two slide grooves 101 can be formed on the groove walls of the accommodation groove, communicating with the accommodation groove. The second moving component 20 can include slide rails 201 on two opposite side surfaces. A part of the second moving component 20 can be arranged in the accommodation groove. The slide rail 201 can slidably match with the slide groove 101. The path where the slide rail 201 is can be the first moving path.

The first friction component 40 may be fixed to the first moving component 10. The first friction component 40 can form a surface contact with the second moving component 20.

The first moving component 10 can slide along the extension direction of the slide rail 201. The first friction component 40 can move synchronously with the first moving component 10. The first friction component 40 can move relative to the second moving component 20 to generate sliding friction along the straight path. The slide friction can provide the damping force for the whole system.

The second moving component 20 and the third moving component 30 can have a second moving path that is an arc. For example, the third moving component 30 can be a rotation shaft, while the second moving component 20 can be rotatably connected to the rotation shaft. The second moving component 20 can include a transmission component and a rotation component. The transmission component can be configured to be slidably connected to the first moving component 10. The rotation component can be configured to be rotatably connected to the rotation shaft. A first cam can be formed at the end surface of the rotation component. A second cam can be movably sleeved on the rotation shaft. The first cam and the second cam can form the second friction component 50. When the second moving component 20 rotates relative to the third moving component 30, the second friction component 50 can generate rotation friction and torque on the arc-path. The rotation friction and the torque can be used to provide the damping force on the rotation component.

The third moving component 30 can be fixed to the base 60. The transmission component of the second moving component 20 can be slidably connected to the first moving component 10, while the rotation component can be rotatably connected to the third moving component 30. The central axis of the rotation component can be defined as the rotation axis.

For example, the flipping component can be a support plate. The first moving component 10 can be connected to the support plate. The first moving component 10 can move linearly along a direction away from the rotation axis. The first moving component 10 can drive the support plate to gradually move away from the rotation component. The first moving component 10 can move linearly in the direction toward the rotation axis. The first moving component 10 can drive the support plate to move close to the rotation component. The support plate can realize the corresponding support function when moving away from or close to the rotation component.

The first moving component 10 and the second moving component 20 can move linearly relative to each other. When the first friction component 40 moves with the first moving component 10, the first friction component 40 can provide the damping force. Meanwhile, the first friction component 40 can drive the support plate to move relative to the rotation component to realize the corresponding support function.

The second moving component 20 and the third moving component 30 can rotate relative to each other. When the second moving component 20 rotates with the first moving component 10, the second moving component 20 can rotate relative to the third moving component 30. The second friction component 50 can provide a damping force in the arc-path to provide the damping force in the opening and closing direction of the flip apparatus.

In some embodiments, when the first moving component 10, the second moving component 20, and the third moving component 30 move relative to each other, the first friction component 40 can provide the damping force in the straight path, and the second friction component 50 can provide the damping force in the arc path. Thus, the stability of the flip apparatus can be ensured in the first status and the second status, and a stable opening and closing tactile feedback can be provided.

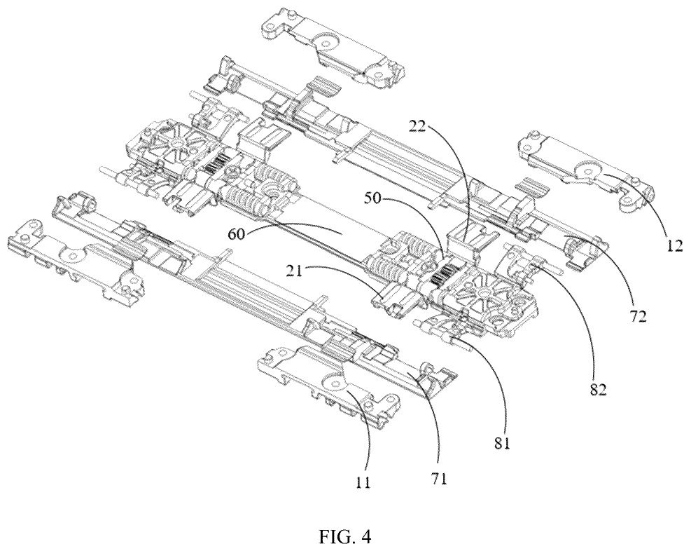

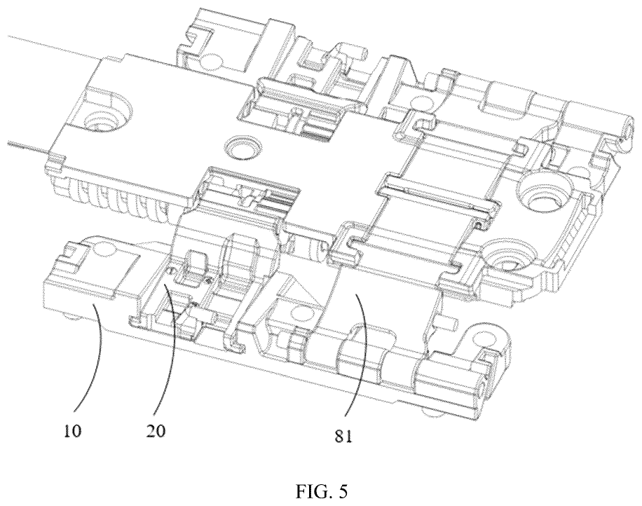

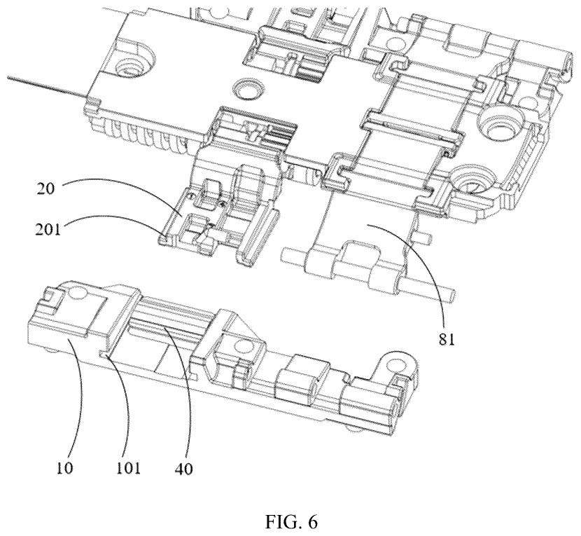

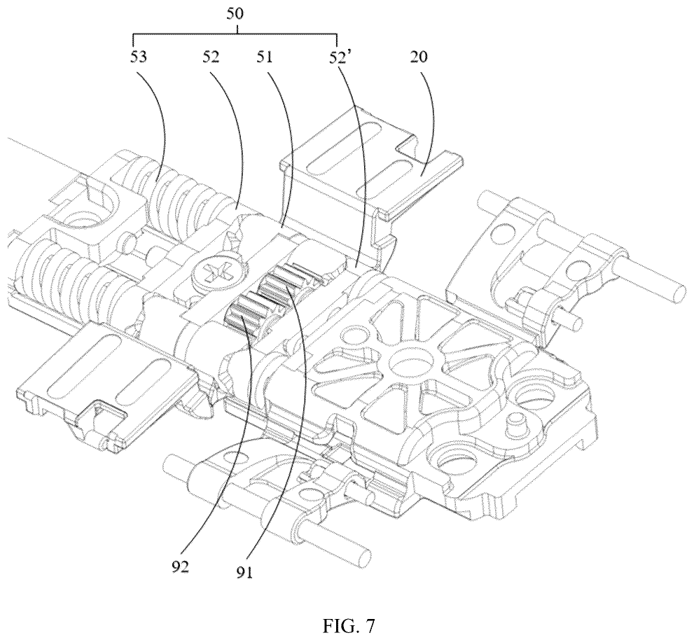

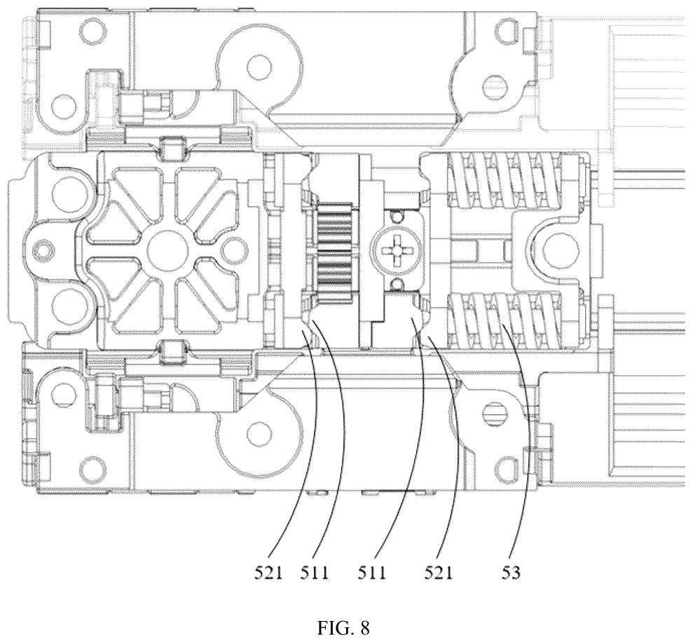

FIG. 4 illustrates a schematic exploded diagram of a flip apparatus according to some embodiments of the present disclosure. FIG. 5 illustrates a schematic assembly diagram of a first moving component, a second moving component, and a first trajectory group according to some embodiments of the present disclosure. FIG. 6 illustrates a schematic exploded diagram of a first moving component, a second moving component, and a first trajectory group according to some embodiments of the present disclosure. FIG. 7 illustrates a schematic structural diagram of a second friction component according to some embodiments of the present disclosure. FIG. 8 illustrates a schematic structural diagram of a second friction component according to some embodiments of the present disclosure.

In embodiments of the present disclosure, as shown FIGS. 4-8, the flip apparatus includes a torque group, a trajectory group, and a first support plate 71. The first friction component 40, the second friction component 50, the second moving component 20, and the third moving component 30 belong to the torque group. The trajectory path can provide a moving path for the flip apparatus to move from the first status to the second status. The first moving component 10 can be a fixed block, which is fixed to the body of the electronic device and is movably connected to the trajectory group. The trajectory group can be rotatably connected to the torque group via the first moving component 10. The first support plate 71 can be movably connected to the torque group and movably connected to the trajectory group.

In some embodiments, the flip apparatus can include the torque group, the trajectory group, and the first support plate. When the flip apparatus switches from the first status to the second status, the torque group can be configured to provide the damping force. The trajectory group can provide navigation for the moving trajectory of the torque group, the first moving component 10, and the first support plate 71.

The first support plate 71 can be configured to provide the support function. When the flip apparatus is in the unfolded status, the first support plate 71 can provide the first support function for the display screen. When the flip apparatus is in the folded status, the first support plate 71 can provide the second support function for the display screen.

The moving component 20 can include a transmission component and a rotation component. The transmission component can be in a plate shape. A transition component can be formed between the transmission component and the rotation component. The shape of the transition component can be set according to the support function of the first support plate 71. For example, the transition component can be in an L shape. The L-shaped transition component can be formed on an end of the transmission component close to the rotation component.

The first moving component 10 can have a plate-shaped body. The first moving component 10 can be a fixed block. The first moving component 10 can be slidably connected to the transmission component of the second moving component 20. A side of the first moving component 10 facing the transmission component can include two opposing slide grooves 101. Two slide rails 201 can be formed on two opposing side surfaces of the transmission component. The slide rail 201 can cooperate with the slide groove 101. The third moving component 30 can be mounted at the base 60. The rotation component can be rotatably connected to the third moving component 30.

The transmission component can have two opposing sides. The first moving component 10 and the first support plate 71 can be arranged on two opposing sides of the transmission component. The first support plate 71 can be movably connected to the first moving component 10. The first support plate 71 can be movably connected to the transmission component of the second moving component 20.

The first moving component 10 can be a fixed block. The fixed block can be connected to one of the two rotatable bodies of the electronic device. The first support plate 71 can be movably connected to the fixed block.

For example, a first guidance groove in an arc shape can be formed on the end surface of the first moving component 10. A first guidance component matching the first guidance groove can be formed on the end surface of the first support plate 71. The first guidance component can slide along the first guidance groove. Then, the first support plate 71 and the first moving component 10 can form the first rotation pair therebetween through the first guidance component and the first guidance groove. The first guidance component and the first guidance groove can form the first guidance structure.

A second guidance component can be formed on the side of the transmission component away from the first moving component 10. A second guidance groove in an arc shape can be formed on the first support plate 71. The second guidance component can slide along the second guidance groove. A second rotation pair can be formed by the second guidance component and the second guidance groove between the first support plate 71 and the second moving component 20. The second guidance component and the second guidance groove can form the second guidance structure.

The first support plate 71 can be movably connected to the first moving component 10 through the first guidance structure. The first support plate 71 can be movably connected to the second moving component 20 through the second guidance structure.

An external force can be applied to the first moving component 10. The first moving component 10 can move linearly relative to the transmission component of the second moving component 20 during the transmission process. The first moving component 10 can move linearly in a direction away from the rotation component. The first moving component 10 can drive the first support plate 71 to gradually move away from the rotation component. The first moving component 10 can move linearly in a direction toward the rotation component. The first moving component 10 can drive the first support plate 71 to gradually approach the rotation component.

When the first support plate 71 synchronously rotates with the first moving component 10, under the guidance of the two rotation pairs of the first guidance structure and the second guidance structure, the first support plate 71 can rotate relative to the first moving component 10. Thus, the rotation angle of the first support plate 71 can be greater than the rotation angle of the first moving component 10.

By switching from the unfolded status to the folded status, the first moving component 10 can rotate 90 degrees. The first support plate 71 can rotate an angle greater than 90 degrees. For example, the first support plate 71 can rotate by an angle of 100 degrees, 105 degrees, or 110 degrees. Thus, the first support surface of the first support plate 71 and the top surface of the base 60 can form an appropriate accommodation space to accommodate the bending component of the display screen.

By switching from the unfolded status to the folded status, the first moving component 10 can rotate and move simultaneously in a direction away from the rotation component. The first moving component 10 can drive the first support plate 71 to move in a direction away from the rotation component. Thus, a larger accommodation space can be formed between the first support surface of the first support plate 71 and the top surface of the base 60 to accommodate the bending component of the display screen.

The trajectory group can include at least one trajectory assembly. The trajectory assembly can include a first trajectory part and a second trajectory part that are connected to each other. The base 60 can include an arc-shaped slide track. The first trajectory part can be slidably arranged at the arc-shaped slide track. The second trajectory part can be hinged with the first moving component 10. The first moving component 10 can include a first hinge base. The first hinge base can include a first shaft hole. The second trajectory part can include a second hinge base. The second hinge base can include a second shaft hole. The first hinge base and the second hinge base can be staggered. A pin can pass through the first shaft hole of the first hinge base and the second shaft hole of the second hinge base to realize the hinge connection between the first moving component 10 and the second trajectory part.

The first trajectory part can move along the arc-shaped slide track to guide the rotation and linear movement of the first moving component 10. The second trajectory part can guide a preset rotation angle of the first moving component 10. When the flip apparatus switches from the unfolded status to the folded status, the rotation angle of the trajectory assembly can be greater than 90 degrees. The first moving component 10 can be hinged to the second trajectory part. The rotation angle of the first moving component 10 can be 90 degrees. That is, in the folded status, the first moving component 10 can be perpendicular to the base 60 to ensure the body of the electronic device connected to the first moving component 10 is perpendicular to the base 60.

The first friction component 40, the second friction component 50, the second moving component 20, and the third moving component 30 can form the torque group. When the first friction component 40 moves linearly with the first moving component 10, the first friction component 40 can generate a constant damping force. When the second moving component 20 rotates relative to the third moving component 30, the second friction component 50 can generate a changing damping force.

When the flip apparatus switches from the unfolded status to the folded status, the moving relationships of the components are described below.

When a pushing force is applied to the first moving component 10 toward the central surface of the base 60, the first trajectory part of the trajectory group can rotates along the arc-shaped slide track from a first end to a second end of the arc-shaped slide track to provide guidance to the rotation and linear movement of the first moving component 10. The first end of the arc-shaped slide track can be an end close to the central surface of the base 60. The second end of the arc-shaped slide track can be an end away from the central surface of the base 60.

The first moving component 10 can drive the second moving component 20 to rotate relative to the third moving component 30 during the movement. Meanwhile, the first moving component 10 can drive the first support plate 71 to move linearly. The first support plate 71 can rotate relative to the first moving component 10 under the guidance of the first rotation pair and the second rotation pair. Then, when switching from the unfolded status to the folded status, the rotation angle of the first moving component 10 can be 90 degrees, and the rotation angle of the first support plate 71 can be greater than 90 degrees. Meanwhile, the first support plate 71 can move away from the rotation component of the second moving component 20. Thus, in the folded status, the first support plate 71 and the top surface of the base 60 can form the appropriate accommodation space to accommodate the bending component of the display screen.

The first moving component 10 can be connected to the first body. When switching from the unfolded status to the folded status, the first moving component 10 can rotate by 90 degrees, and the first body can also rotate by 90 degrees, ensuring that the first body and the second body are parallel to each other.

The movement relationships between the components when the flip apparatus switches from the folded status to the unfolded status are described below.

When a pulling force is applied to the first moving component 10 away from the central surface of the base 60, the first trajectory part of the trajectory group can rotate along the arc-shaped slide track from the second end to the first end to provide guidance to the rotation and the linear movement of the first moving component 10.

During the movement of the first moving component 10, the first moving component 10 can drive the second moving component 20 to rotate relative to the third moving component 30. The first moving component 10 can simultaneously drive the first support plate 71 to move linearly. Under the guidance of the first rotation pair and the second rotational pair, the first support plate 71 can rotate relative to the first moving component 10. Then, the first moving component 10 can rotate by 90 degrees, and the first support plate 71 can rotate by more than 90 degrees. Meanwhile, the first support plate 71 can move close to the rotation component of the second moving component 20. Thus, in the unfolded status, the first support surface of the first support plate 71 can be parallel to the top surface of the base 60. The first support surface of the first support plate 71 can be coplanar with the first surface of the first body to support the display screen. Additionally, the end of the first support surface of the first support plate 71 can be close to the rotation component of the second moving component, providing better support for the display screen.

In some embodiments, the trajectory group can provide the moving path for the flip apparatus to move from the first status to the second status. The second moving component 20, the third moving component 30, the first friction component 40, and the second friction component 50 can provide a damping force. The first support plate 71 can be movably connected to the trajectory group and the torque group. Thus, in the first status, the first support surface of the first support plate 71 can be parallel to the top surface of the base 60, and the first support plate 71 can be close to the rotation component of the second moving component 20. In the second status, the first support surface of the first support plate 71 can have a preset angle with the top surface of the base 60, and the first support plate 71 can move away from the rotation component of the second moving component 20. The first support plate 71 can realize different support functions in the first status and the second status to meet the application requirements.

In embodiments of the present disclosure, as shown in FIGS. 2 and 3, the first friction component 40 is an elastic component, and the second moving component 20 is a transmission arm. The fixed block has a moving path for the transmission arm. The fixed block can correspond to the moving path and include a limitation groove. The elastic component is arranged in the limitation groove to limit the movement of the elastic component in a first dimension. The transmission arm is arranged in the moving path to limit the movement in a second dimension. The transmission arm is in the moving path. The elastic component can be subjected to the pressing force in the first direction of the transmission arm of the second dimension to provide an elastic force in the second direction of the second dimension.

In some embodiments, the first moving component 10 can be the fixed block. The second moving component 20 can be the transmission arm. The fixed block can have the moving path of the transmission arm. That is, when the fixed block slides linearly relative to the transmission arm, the first friction component 40 can remain in contact with the transmission arm.

The limitation groove can be formed on a side of the fixed block facing the transmission arm. The first friction component 40 can be the elastic component. The boundary of the elastic component can be embedded into the limitation groove. The limitation groove can be configured to limit the movement of the elastic component in the first dimension. That is, the elastic component can be at a fixed position at the fixed block. When the fixed block moves linearly relative to the transmission arm, the elastic component can synchronously move linearly with the fixed block.

At least a part of the elastic component can abut against the side of the transmission arm facing the fixed block. The transmission arm can apply a pressing force on the elastic component in a second dimension direction to limit the elastic component from moving along the second dimension direction. The second dimension direction can intersect with the first dimension direction. The second dimension direction can be perpendicular to the first dimension direction. That is, the second dimension direction can be perpendicular to the direction in which the fixed block moves linearly.

The elastic component can be clamped between the opposing surfaces of the fixed block and the transmission arm. The transmission arm can apply pressure to the elastic component in the first direction of the second dimension. Based on the principle of action and reaction, the elastic component can provide an elastic force in the second direction of the second dimension. The second direction can be parallel and opposite to the first direction.

The elastic force provided by the elastic component can ensure the elastic component and the transmission arm remain in the abutting status. When the fixed block moves linearly relative to the transmission arm, the elastic component can remain in friction contact with the transmission arm to generate sliding friction. The sliding friction can be the damping force for the transmission arm along the first moving path.

The elastic component can ensure the existence of the sliding friction when the fixed block moves linearly relative to the transmission arm. In addition, the elastic component can have elastic deformation. During the linear movement of the fixed block, the elastic component can slightly deform along the second dimension direction, ensuring smooth sliding of the fixed block along the first dimension direction.

In some embodiments, the elastic component can be a metal sheet with a protrusion in the second direction of the second dimension. The metal sheet can form a surface contact with the transmission component of the second moving component 20. When the metal sheet slides relative to the transmission component, the contact area between the metal sheet and the transmission component can remain relatively stable, ensuring stable sliding friction, which can be beneficial to provide a constant damping force for the system.

In some embodiments, the elastic component can also be a spring. The spring can be a conical spring. A large end of the conical spring can be fixed at the limitation groove of the first moving component 10, while a small end of the conical spring can abut against the transmission component of the second moving component 20. When the conical spring slides relative to the transmission component, sliding friction can be generated to provide a constant damping force for the system.

In embodiments of the present disclosure, as shown in FIG. 7, the second friction component 50 includes a first cam 51, a second cam, and a torsion spring 53. The first cam 51 is arranged at the end of the transmission arm and is sleeved at the third moving component 30 as a core shaft. The two opposing side surfaces of the first cam 51 have symmetrically arranged first protrusions 511. Two second cams are sleeved on the core shaft on two sides of the first cam 51. The second protrusion 521 of the second cam can at least correspond to the first protrusion 511 of the first cam 51. The torsion spring 53 is also sleeved at the core shaft.

When the flip apparatus moves from the first status to the second status, the transmission arm can rotate relative to the core shaft. The first protrusions 511 of the first cam 51 and the second protrusions 521 of the second cams can switch from a staggered match to a corresponding match, and then from the corresponding match to the staggered match. Thus, the torsion spring 53 can deform to provide a changing elastic force.

In some embodiments, the third moving component 30 can be a core shaft. The core shaft can be fixedly mounted at the base 60. The second moving component 20 can be a transmission arm. The first moving component 10 and the third moving component 30 can be connected and transmit movement through the second moving component 20. The transmission arm can include the transmission component slidably connected to the first moving component 10 and the rotation component rotatably connected to the third moving component 30.

The second friction component 50 can include the first cam 51, the second cams, and the torsion spring 53. The transmission arm can include the transmission component and the rotation component. The rotation component can be the first cam 51. The first cam 51 can be rotatably connected to the core shaft. The first protrusions 511 can be formed on the two opposing side surfaces of the first cam 51 and first concave components staggered with the first protrusions 511.

Two second cams can be sleeved at the core shaft. The two second cams can be arranged on two opposing sides of the first cam 51. The two second cams can include a second cam 52 close to the torsion spring 53 and a second cam 52′ away from the torsion spring 53. The second cam 52 can be movably sleeved at the core shaft. The second cam 52 can move along the axis of the core shaft. The second cam 52′ can be fixedly sleeved at the core shaft. The second protrusion 521 and the second concave component staggered with the second protrusion 521 can be formed on the side surface of the second cam 52 facing the first cam 51. The second cam 521 and the second concave component staggered with the second protrusion 521 can be formed on the side surface of the second cam 52′ facing the first cam 51.

The torsion spring 53 can be sleeved on the core shaft. A fixed component can be sleeved on the core shaft. The fixed component can be arranged at the end of the core shaft. The torsion spring 53 can be arranged between the second cam 52 away from the trajectory group and the fixed component.

When the first cam 51 rotates relative to the core shaft, the first protrusions 511 of the first cam 51 can switch from the staggered match to the corresponding match, and from the corresponding match to the staggered match with the second protrusion 521 of the second cam 52 and the second protrusion 521 of the second cam 52′.

When the flip apparatus is in the unfolded status, the first protrusions 511 of the first cam 51 can have a staggered match with the second protrusion 521 of the second cam 52 and the second protrusion 521 of the second cam 52′. That is, the first protrusion 511 of the first cam 51 can be arranged at the second concave components of the first cam 52 and the second cam 52′. Then, the torsion spring 53 can be subject to the smallest elastic force and can provide the smallest torque.

When the flip apparatus is switched from the unfolded status to the half unfolded status, the first protrusions 511 of the first cam 51 can be switched from the staggered match to the corresponding match with the second protrusion 521 of the second cam 52 and the second protrusion 521 of the second cam 52′. That is, the first protrusions 511 can correspond to the second protrusions 521. The second cam 52 can be subject to the abutting force of the first cam 51 and can move along the axial direction of the core shaft toward the torsion spring 53. The second cam 52 can continuously compress the torsion spring 53. The elastic force received by the torsion spring 53 can gradually increase. Meanwhile, the second cam 52′ can be subject to the abutting force of the first cam 51 to apply a pulling force to the core shaft toward the side away from the torsion spring 53. Thus, the torsion spring 53 can be further compressed. When the first protrusions 511 corresponds to the second protrusions 521, the torsion spring 53 can be subject to the largest elastic force, and the torsion spring 53 can provide the largest torque. When switching from the unfolded status to the half unfolded status, the elastic force received by the torsion spring 53 can gradually increase, and the torque can gradually increase.

When the flip apparatus is switched from the half unfolded status to the folded status, the first protrusions 511 of the first cam 51 can be switched from the corresponding match to the staggered match with the second protrusion 521 of the second cam 52 and the second protrusion 521 of the second cam 52′. That is, first protrusions 511 of the first cam 51 can move to a next second concave component of the second cam 52 and a next second concave component of the second cam 52′. When switching from the half unfolded status to the folded status, the elastic force received by the torsion spring 53 can gradually decrease, and the torque provided by the torsion spring 53 can also gradually decrease.

When the flip apparatus is switched from the unfolded status to the folded status, the first protrusions 511 of the first cam 51 can be switched from the staggered match to the corresponding match, and then from the corresponding match to the staggered match, with the second protrusion 521 of the second cam 521 and the second protrusion 521 of the second cam 52′. The elastic force received by the torsion spring 53 can gradually increase first, and then gradually decrease. The elastic force of the torsion spring 53 can be the damping force of the transmission arm moving in the second moving path.

A protrusion 511 of the first cam 51 can friction-cooperate with a second protrusion 521 of the second cam 52. The other first protrusion 511 of the first cam 51 can friction-cooperate with the second protrusion of the second cam 52′. When the diameters of the core shaft, the first cam 51, the second cam 52, and the second cam 52′ decrease, a sufficient damping force can also be provided. In addition, the second cam 52 and the second cam 52′ can be configured to ensure the transmission reliability of the transmission arm.

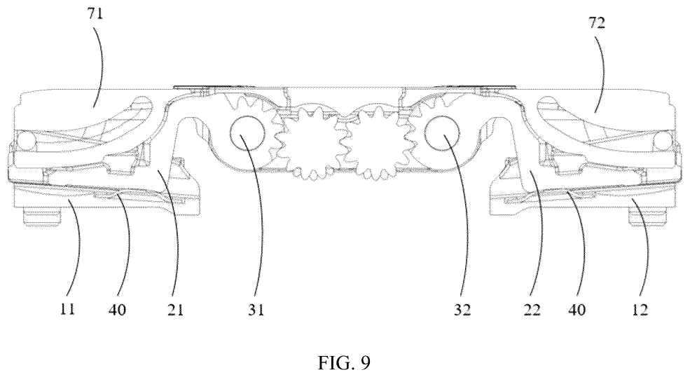

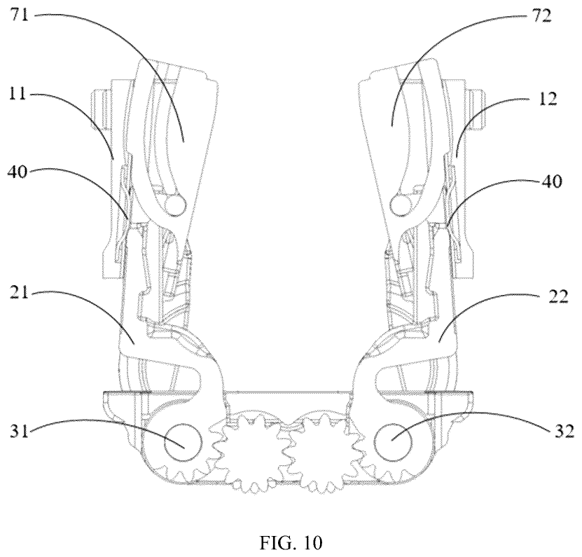

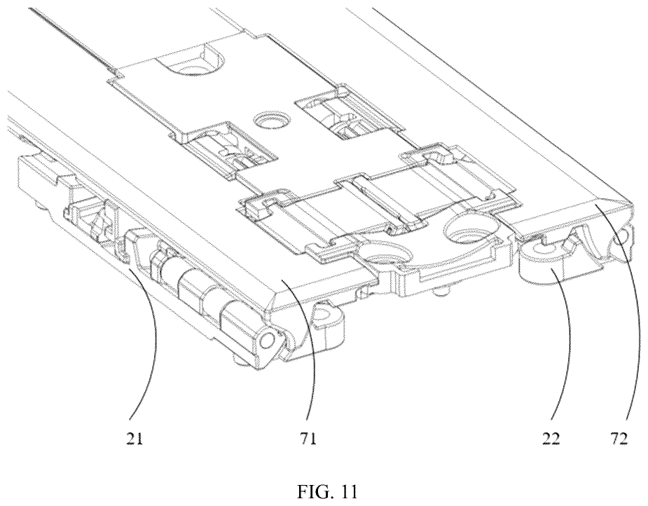

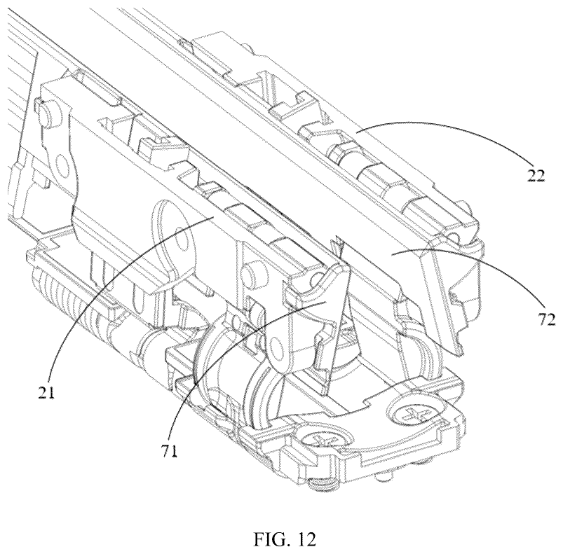

FIG. 9 illustrates a schematic structural diagram of a flip apparatus in a first status according to some embodiments of the present disclosure. FIG. 10 illustrates a schematic structural diagram of a flip apparatus in a second status according to some embodiments of the present disclosure. FIG. 11 illustrates a schematic structural diagram of a flip apparatus in a first status according to some embodiments of the present disclosure. FIG. 12 illustrates a schematic structural diagram of a flip apparatus in a second status according to some embodiments of the present disclosure.

In embodiments of the present disclosure, as shown in FIG. 4, and FIGS. 9-12, the torque group also includes components mirror-arranged with the first friction component 40, the second friction component 50, the second moving component 20, and the third moving component 30. The flip apparatus further includes a moving component mirror-arranged with the first moving component 10, and a second support plate 72 mirror-arranged with the first support plate 71. When the flip apparatus is in the first status, the first support plate 71 and the second support plate 72 can form a plane. When the flip apparatus is in the second status, the first support plate 71 and the second support plate 72 can form an accommodation space.

In some embodiments, the torque group can include two torque components arranged in mirror symmetry about the central surface of the base 60. Two sides of the central surface of the base 60 can include a first side and a second side of the base 60. A torque component can be provided on each of the first side and the second side. The torque component can include the first friction component 40, the second friction component 50, the second moving component 20, and the third moving component 30.

The first moving component 10 can be arranged on the first side of the base 60. The moving component mirror-arranged with the first moving component 10 can be arranged on the second side. The first support plate 71 can be arranged on the first side of the base 60. The second support plate 72 mirror-arranged with the first support plate 71 can be arranged on the second side.

To facilitate description below, the first moving component 10 and the moving component mirror-arranged with the first moving component 10 can be defined as a first fixed block 11 and a second fixed block 12, respectively. The two moving components 20 mirror-arranged can be defined as the first transmission arm 21 and the second transmission arm 22. The two third moving components 30 mirror-arranged can be defined as a first core shaft 31 and a second core shaft 32, respectively.

When the flip apparatus is in the unfolded status, the first support surface of the first support plate 71 and the second support surface of the second support plate 72 can form a plane. The first support surface and the second supporting surface can be used to support the middle portion of the display screen. The middle portion can be the flexible bending component of the display screen.

When the flip apparatus is switched from the unfolded status to the folded status, the trajectory group can provide navigation for the moving paths of the rotation and the linear movement of the first fixed block 11 and the second fixed block 12. During the movement, the first fixed block 11 can drive the first support plate 71 to move. Under the guidance of the first rotation pair and the second rotation pair, the rotation angle of the first support plate 71 can be greater than the rotation angle of the first fixed block 11. During the movement, the second fixed block 12 can drive the second support plate 72 to move. Under the guidance of the first rotation pair and the second rotation pair, the rotation angle of the second support plate 72 can be greater than the rotation angle of the second fixed block 12.

When the flip apparatus is in the folded status, the first fixed block and the second fixed block 12 can be perpendicular to the base 60. The first support surface of the first support plate 71 and the second support surface of the second support plate 72 can form a gradually changing accommodation space. The first support surface and the second support surface can support the flexible bending component of the display screen.

The first friction component 40 and the second friction component 50 can provide the constant damping force and the changing damping force to the system, respectively. The diameter sizes of the first core shaft 31 and the first cam 51, the second cam 52, and the second cam 52′ sleeved at the first core shaft can be further reduced. The diameter sizes of the second core shaft 32, and the first cam 51, the second cam 52, and the second cam 52′ sleeved at the second core shaft can be further reduced. Thus, the distance between the first core shaft 31 and the second core shaft 32 can be reduced.

The distance between the first core shaft 31 and the second core shaft 32 can be reduced. After the flip apparatus is folded, the flip apparatus can have lightweight and be thinned.

Further, the torque group can also include a first fixed frame, a first movable frame, and a second movable frame arranged sequentially along the axial direction of the core shaft. The second cam 52 can be arranged on a side of the first movable frame facing the first cam 51. The second cam 52′ can be arranged on a side of the first movable frame facing the first cam 51. Two second cams 52 can be arranged at the first movable frame at an interval. Two second cams 52′ can be arranged at the second movable frame at an interval. Two shaft holes matching the first core shaft 31 and the second core shaft 32 can be formed on the first fixed frame.

During assembly, the first core shaft 31 can pass sequentially through the first fixed frame, the second cam 52 of the first movable frame, the first cam 51, and the second cam 52′ of the second movable frame. The second core shaft 32 can pass sequentially through the first fixed frame, the second cam 52 of the first movable frame, the first cam 51, and the second cam 52′ of the second movable frame. The assembly process can be convenient. Additionally, the first movable frame and the second movable frame can be beneficial to synchronize the rotation of the two first cams 51.

Further, the torque group can also include a second fixed frame, a first transmission gear 91, and a second transmission gear 92. The second fixed frame can be arranged between the first movable frame and the second movable frame. One end of the first transmission gear 91 can be rotatably connected to the second fixed frame. The other end of the first transmission gear 91 can be rotatably connected to the second movable frame. One end of the second transmission gear 92 can be rotatably connected to the second fixed frame. The other end of the second transmission gear 92 can be rotatably connected to the second movable frame. The first transmission gear 91 and the second transmission gear 92 can be meshed together.

A gear meshing with the first transmission gear 91 and the second transmission gear 92 can be provided at the circumferential surface of the first cam 51. When the two first cams 81 rotate, one first cam 51 can mesh with the first transmission gear 91, and the other one first cam 51 can mesh with the second transmission gear 92. The first transmission gear 91 can be meshed with the second transmission gear 92 to ensure the two first cams 51 rotate synchronously.

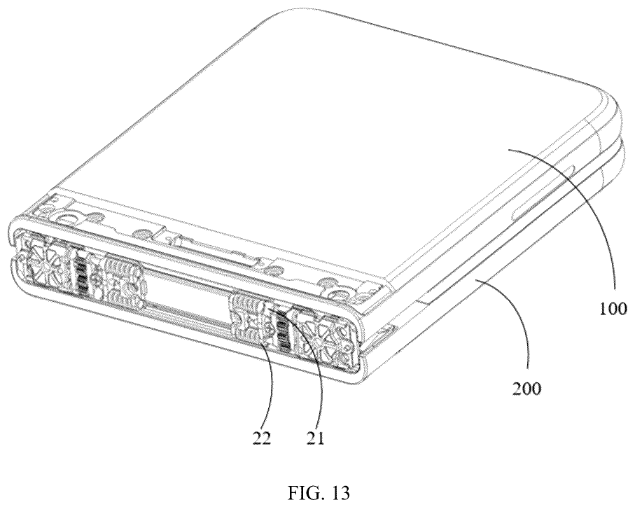

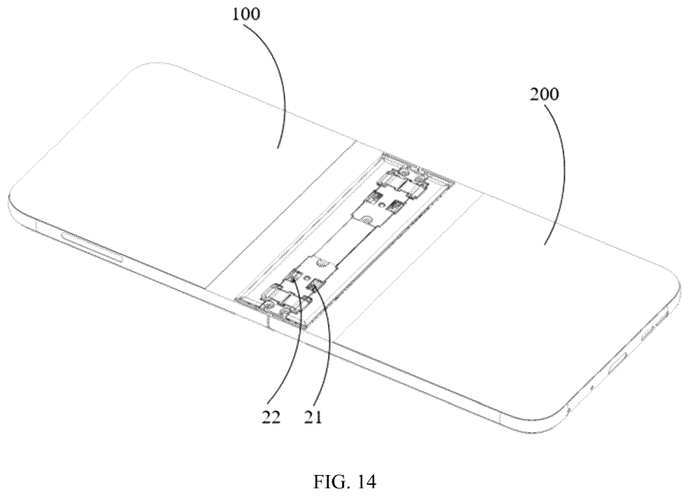

FIG. 13 illustrates a schematic structural diagram of an electronic device in a folded status according to some embodiments of the present disclosure. FIG. 14 illustrates a schematic structural diagram of an electronic device in an unfolded status according to some embodiments of the present disclosure.

As shown in FIGS. 13 and 14, the present disclosure further provides an electronic device. The electronic device includes a first body 100, a second body 200, and a flip apparatus. The first body 100 and the second body 200 can be switched from a first relative position to a second relative position via the flip apparatus. When the first body 100 and the second body 200 are switched from the first relative position to the second relative position, the first friction component 40 and the second friction component 50 of the flip apparatus can act together to provide the damping force. The first friction component 40 and the second friction component 50 can be different.

In some embodiments, the first body 100 and the second body 200 can be symmetrically arranged about the central surface of the base 60. When the flip apparatus moves from the first status to the second status, the first body 100 and the second body 200 can be switched from the first relative position to the second relative position.

When the first body 100 and the second body 200 are in the first relative position, the first surface of the first body 100 and the second surface of the second body 200 can form a plane. The first surface and the second surface can be configured to support the display screen or the support object in the unfolded status.

When the first body 100 and the second body 200 are in the second relative position, the first surface of the first body 100 and the second surface of the second body 200 can be parallel to each other. The first surface and the second surface can be configured to support the display screen or the support object in the folded status.

The first body 100 and the second body 200 can be switched between the first relative position and the second relative position. The first friction component 40 and the second friction component 50 can be distributed at different positions of the electronic device. The first friction component 40 and the second friction component 50 can act together to provide the damping force for the system, which is beneficial for the slim design of the flip apparatus. Thus, the electronic device can be facilitated with a slim design.

In embodiments of the present disclosure, the electronic device can further include a display screen. A first portion of the display screen can be fixed at the first surface of the first body 100. A second portion of the display screen can be fixed at the second surface of the second body 200. The display screen can further include the flexible bending component between the first portion and the second portion.

The flip apparatus can include a base 60. The base can include a length direction and a width direction. Along the width direction of the base 60, the two opposite sides of the base 60 can be defined as the first side and the second side of the base 60, respectively. Along the length direction of the base 60, the two opposite ends of the base 60 can be defined as the first end and the second end of the base 60, respectively.

The flip apparatus can include a torque group and a trajectory group. A pair of torque groups and a pair of trajectory groups can be arranged at intervals along the length direction of the base 60. One torque group and one trajectory group on an end of the base 60 can be taken as an example for description.

Each torque group can include a first torque component and a second torque component arranged about the central surface of the base 60. The first torque component and the second torque component can include two second moving components 20, two third moving components 30, two first friction components 40, and two second friction components 50.

The two first moving components 10 can be mirror-arranged about the central surface of the base 60.

Each trajectory group can include a first trajectory assembly 81 and a second trajectory assembly 82 mirror-arranged about the central surface of the base 60. The base 60 can include two arc-shaped slide tracks corresponding to the two trajectory assemblies. The trajectory assembly can include a first trajectory part and a second trajectory part. The first trajectory part can rotate along the arc-shaped slide track. The second trajectory part can be hinged to the first moving component 10. The trajectory assembly can provide guidance for the moving paths of the rotation and the linear movement of the first moving component 10.

The two first moving components 10 that are mirror-arranged can be defined as the first fixed block 11 and the second fixed block 12, respectively. The two second moving components 20 that are mirror-arranged can be defined as the first transmission arm 21 and the second transmission arm 22, respectively. The two third moving components 30 that are mirror-arranged can be defined as the first core shaft 31 and the second core shaft 32.

Two first transmission arms 21 can be arranged at an interval along the length direction of the base 60 on the first side of the base 60. The first support plate 71 and the two first transmission arms 21 can be movably connected through two second guidance structures. The first fixed block 11 and the second fixed block 12 can be arranged at an interval on the first side of the base 60 along the length direction of the base 60. The first support plate 71 can be movably connected to the first fixed block 11 and the second fixed block 12 through two first guidance structures. The first fixed block 11 and the second fixed block 12 of the first side can be defined as the first fixed assembly.

Two second transmission arms 22 can be arranged at an interval on the second side of the base 60 along the length direction of the base 60. The second support plate 72 and the two second transmission arms 22 can be movably connected to the two guidance structures. The first fixed block 11 and the second fixed block 12 can be arranged at an interval on the second side of the base 60 along the length direction of the base 60. The second support plate 72 can be movably connected to the first fixed block 11 and the second fixed block 12 through the two second guidance structures. The first fixed block 11 and the second fixed block 12 on the second side can be defined as the second fixed assembly.

The first body 100 can be connected to the first fixed block 11 and the second fixed block 12 on the first side of the base 60. The second body 200 can be connected to the first fixed block 11 and the second fixed block 12 on the second side of the base 60.

The display screen can include a first portion, a second portion, and a flexible bending component between the first portion and the second portion. The first surface of the first body 100 can be connected to the first portion of the display screen. The second surface of the second body 200 can be connected to the second portion of the display screen.

When the electronic device is in the unfolded status, the first surface of the first body 100, the second surface of the second body 200, the first support surface of the first support plate 71, and the second support surface of the second support plate 72 can form a co-planar structure.

When the display screen is in the unfolded status, the first surface, the first support surface, the second support surface, and the second surface can support the display screen to ensure the display screen stably remains in the unfolded status.

When the electronic device is switched from the unfolded status to the folded status, a pushing force toward the central surface of the base 60 can be applied to the first body 100 and the second body 200. The first trajectory assembly 81 can provide guidance to the moving paths of the rotation and the linear movement of the first fixed assembly. The second trajectory assembly 82 can provide guidance to the moving paths of the rotation and the linear movement of the second fixed assembly.

The first fixed assembly can drive the first body 100 and the first support plate 71 to rotate toward the central surface of the base 60. The second fixed assembly can drive the second body 200 and the second support plate 72 to rotate toward the central surface of the base 60. During the rotation, the two elastic components between the first fixed assembly and the two first transmission arms 21 and the two elastic components between the second fixed assembly and the two second transmission arms 22 can provide a constant damping force for the system. During the rotation, the first cam 51, the second cam 52, the second cam 52′, and the torsion spring 53 between the two first transmission arms 21 and the two first core shafts 31 on the first side of the base 60 and the first cam 51, the second cam 52, the second cam 52′, and the torsion spring 53 between the two second transmission arms 22 and the two second core shafts 32 on the second side of the base 60 can provide the changing damping force for the system. The constant damping force and the changing damping force can act on the moving system to provide stable opening/closing tactile feedback for the electronic device to improve the user experience.

When the electronic device is switched to the folded status, the first body 100 and the second body 200 can be parallel to each other and close to each other or attached to each other. The first support surface of the first support plate 71 and the second support surface of the second support plate 72 can form a gradually changing accommodation space. The first body 100 can support the first portion of the display screen. The second body 200 can support the second portion of the display screen. The first support surface and the second support surface can support the flexible bending component of the display screen.

The electronic device having the above flip apparatus can have a slim design and stable opening/closing tactile feedback. When the flip apparatus is switched between the first status and the second status, the first body 100, the second body 200, the first support plate 71, and the second support plate 72 can effectively support the display screen.

Those skilled in the art can understand that various features described in embodiments and/or claims of the present disclosure may be combined and/or grouped in various manners, even if such combinations are not explicitly described herein. In some embodiments, without departing from the spirit and teachings of the present disclosure, features from different embodiments and/or claims can be combined in various manners. All such combinations and/or groups are within the scope of the present disclosure.

Although the present disclosure has been illustrated and described with reference to specific exemplary embodiments, those skilled in the art should understand that various modifications in form and detail can be made without departing from the spirit and scope of the present disclosure defined by the appended claims and their equivalents. Therefore, the scope of the present disclosure should not be limited to the described embodiments, but should be determined both by the appended claims and the equivalents of the appended claims.

What is claimed is:

1. A flip apparatus comprising:
a first friction component arranged between a first moving component and a second moving component that move relative to each other; and
a second friction component arranged between the second moving component and a third moving component that move relative to each other, the first friction component being different from the second friction component;
wherein:
when the flip apparatus moves from a first status to a second status, and the first friction component and the second friction component jointly provide a damping force.

2. The flip apparatus according to claim 1, wherein when the flip apparatus moves from the first status to the second status, the first friction component provides a constant damping force, and the second friction component provides a changing damping force.

3. The flip apparatus according to claim 1, wherein:
the first friction component provides a damping force along a first moving path between the first moving component and the second moving component, the first moving path being a linear path; and
the second friction component provides a damping force along a second moving path between the second moving component and the third moving component, the second moving path being an arc-shaped path.

4. The flip apparatus according to claim 3, further comprising:
a torque group including the first friction component, the second friction component, the second moving component, and the third moving component;
a trajectory group providing a moving path for the flip apparatus to move from the first status to the second status;
a fixed block being the first moving component, fixed to a body of the electronic device, and movably connected to the trajectory group, the trajectory group being connected to and transmitting movement to the torque group through the first moving component; and
a first support plate movably connected to the torque group and movably connected to the trajectory group.

5. The flip apparatus according to claim 4, wherein:
the first friction component is an elastic component, the second moving component is a transmission arm, the fixed block includes a moving path of the transmission arm, the fixed block includes a limitation groove corresponding to the moving path, the elastic component is arranged in the limitation groove to limit movement of the elastic component in a first dimension, and the transmission arm is arranged on the moving path to limit movement of the elastic component in a second dimension; and
when the transmission arm is arranged on the moving path, the elastic component is subjected to pressure in a first direction of the second dimension from the transmission arm and provides an elastic force in a second direction of the second dimension.

6. The flip apparatus according to claim 5, wherein the elastic component is a metal sheet having a protrusion in the second direction of the second dimension.

7. The flip apparatus according to claim 4, wherein:
the second friction component is a combination of a first cam, a second cam, and a torsion spring, the first cam is arranged at an end of the transmission arm and sleeved at the third moving component as a core shaft, and first protrusions are symmetrically arranged on two opposite side surfaces of the first cam;
two second cams are sleeved at the core shaft and arranged on two sides of the first cam, second protrusions of the second cams at least correspond to the first protrusions of the first cam;
the torsion spring is sleeved at the core shaft; and
when the flip apparatus moves from the first status to the second status, the transmission arm rotates relative to the core shaft, the first protrusions of the first cam are switched from a staggered match to a corresponding match, and then from the corresponding match to the staggered match with the second protrusions of the second cams to compress the torsion spring to deform to provide a changing elastic force.

8. The flip apparatus according to claim 4,
wherein the torque group further includes components mirror-arranged with the first friction component, the second friction component, the second moving component, and the third moving component;
the flip apparatus further comprising:
a moving component mirror-arranged with the first moving component; and
a second support plate mirror-arranged with the first support plate;
wherein:
when the flip apparatus is in the first status, the first support plate and the second support plate form a plane;
when the flip apparatus is in the second status, the first support plate and the second support plate form an accommodation space.

9. An electronic device, comprising:
a first body;
a second body; and
a flip apparatus, the first body and the second body being switched from a first relative position to a second relative position through the flip apparatus;
wherein:
when the first body and the second body are switched from the first relative position to the second relative position, a first friction component and a second friction component of the flip apparatus jointly provide a damping force, and the first friction component is different from the second friction component.

10. The electronic device according to claim 9, further comprising:
a display screen including a first portion fixed to a first surface of the first body, a second portion fixed to a second surface of the second body, and a flexible bending component arranged between the first portion and the second portion;
wherein:
the flip apparatus further includes:
a torque group including a first torque component and a second torque component that are mirror-arranged;
a trajectory group including a first trajectory assembly and a second trajectory assembly that are mirror-arranged, the first trajectory assembly being connected to and transmitting movement to the first torque component through a first fixed block, and the second trajectory assembly being connected to and transmitting movement to the second torque component through a second fixed block;
a first support plate and a second support plate that are mirror-arranged, the first support plate being movably connected to the first trajectory assembly and the first torque component, and the second support plate being movably connected to the second trajectory assembly and the second torque component;
the first body is connected to the first fixed block, and the second body is connected to the second fixed block;
the first trajectory assembly and he second trajectory assembly provide moving paths for the flip apparatus to move from the first status to the second status to cause the first support plate and the second support plate to switch from a first relative posture to a second relative posture, and the first body and the second body to switch from a first relative position to a second relative position;
in the first relative posture and the first relative position, the first support plate, the second support plate, the first surface, and the second surface form a co-planar structure to support the display screen; and
in the second relative posture and the second relative position, the first support plate and the second support plate enclose to form an area suitable for accommodating the flexible bending component, the first surface and the second surface are parallel to each other, and the first surface and the second surface support the first portion and the second portion of the display screen.

11. The electronic device according to claim 9, wherein:
the first friction component is arranged between a first moving component and a second moving component that move relative to each other; and
the second friction component is arranged between the second moving component and a third moving component that move relative to each other.

12. The electronic device according to claim 11, wherein when the flip apparatus moves from the first status to the second status, the first friction component provides a constant damping force, and the second friction component provides a changing damping force.

13. The electronic device according to claim 11, wherein:
the first friction component provides a damping force along a first moving path between the first moving component and the second moving component, the first moving path being a linear path; and
the second friction component provides a damping force along a second moving path between the second moving component and the third moving component, the second moving path being an arc-shaped path.

14. The electronic device according to claim 13, wherein:
the first friction component is an elastic component, the second moving component is a transmission arm, the fixed block includes a moving path of the transmission arm, the fixed block includes a limitation groove corresponding to the moving path, the elastic component is arranged in the limitation groove to limit movement of the elastic component in a first dimension, and the transmission arm is arranged on the moving path to limit movement of the elastic component in a second dimension; and
when the transmission arm is arranged on the moving path, the elastic component is subjected to pressure in a first direction of the second dimension from the transmission arm and provides an elastic force in a second direction of the second dimension.

15. The electronic device according to claim 14, wherein the elastic component is a metal sheet having a protrusion in the second direction of the second dimension.

16. The electronic device according to claim 13, wherein:
the second friction component is a combination of a first cam, a second cam, and a torsion spring, the first cam is arranged at an end of the transmission arm and sleeved at the third moving component as a core shaft, and first protrusions are symmetrically arranged on two opposite side surfaces of the first cam;
two second cams are sleeved at the core shaft and arranged on two sides of the first cam, second protrusions of the second cams at least correspond to the first protrusions of the first cam;
the torsion spring is sleeved at the core shaft; and
when the flip apparatus moves from the first status to the second status, the transmission arm rotates relative to the core shaft, the first protrusions of the first cam are switched from a staggered match to a corresponding match, and then from the corresponding match to the staggered match with the second protrusions of the second cams to compress the torsion spring to deform to provide a changing elastic force.

17. The electronic device according to claim 13, wherein:
the torque group further includes components mirror-arranged with the first friction component, the second friction component, the second moving component, and the third moving component;
the flip apparatus further includes:
a moving component mirror-arranged with the first moving component; and
a second support plate mirror-arranged with the first support plate;
when the flip apparatus is in the first status, the first support plate and the second support plate form a plane; and
when the flip apparatus is in the second status, the first support plate and the second support plate form an accommodation space.
